(19) United States
(12) Patent Application Publication
(10) Pub. No.: US 2024/0319293 A1
(43) Pub. Date: Sep. 26, 2024

(54) SYSTEMS FOR AUTOMATED VOLUMETRY, BLENDING AND DISPENSING OF GAS

(71) Applicant: Polarean, Inc., Durham, NC (US)

(72) Inventors: Andrew K. Dummer, Chapel Hill, NC (US); Matthew Linford, Chapel Hill, NC (US)

(21) Appl. No.: 18/593,254

(22) Filed: Mar. 1, 2024

Related U.S. Application Data
(60) Provisional application No. 63/492,005, filed on Mar. 24, 2023.

(51) Int. Cl. G01R 33/28; F17C 9/00

(52) U.S. Cl. CPC G01R 33/282; F17C 9/00; F17C 2201/058; F17C 2205/0326; F17C 2221/014; F17C 2221/016; F17C 2223/0161; F17C 2227/0142; F17C 2250/03; F17C 2250/043; F17C 2270/0536

(57) ABSTRACT

Gas dispensing control systems that use a gas expansion chamber with a plunger in fluid communication with both a vacuum pump and a nitrogen supply with a controller that calculates and dispenses standard volumes of gas based, at least in part, on local environmental conditions. The dispensed gas can be hyperpolarized ¹²⁹Xe for MRI imaging.

### RELATED APPLICATIONS

This patent application claims the benefit of and priority to U.S. Provisional Application Ser. No. 63/492,005, filed Mar. 24, 2023, the contents of which are hereby incorporated by reference as if recited in full herein.

### FIELD OF THE INVENTION

The present invention relates to dispensing gas that is particularly suitable for hyperpolarized gas for magnetic resonance imaging (“MRI”) and spectroscopy applications.

### BACKGROUND

Conventionally, MRI has been used to produce images by exciting the nuclei of hydrogen atoms (present in water molecules) in the human body. MRI imaging with polarized noble gases can produce improved images of certain areas and regions of the body. Polarized Helium-3 (“³He”) and Xenon-129 (“¹²⁹Xe”) have been found to be particularly suited for this purpose.

Hyperpolarizers are used to produce and accumulate polarized noble gases. Hyperpolarizers artificially enhance the polarization of certain noble gas nuclei (such as ¹²⁹Xe or ³He) over the natural or equilibrium levels, i.e., the Boltzmann polarization. Such an increase is desirable because it enhances and increases the Magnetic Resonance Imaging (“MRI”) signal intensity, allowing physicians to obtain better images of the substance in the body. See U.S. Pat. No. 5,642,625 to Cates et al. and U.S. Pat. No. 5,545,396 to Albert et al., the contents of which are hereby incorporated herein by reference as if recited in full herein.

In order to produce the hyperpolarized gas, the noble gas is typically blended with optically pumped alkali metal vapors such as rubidium (“Rb”). These optically pumped metal vapors collide with the nuclei of the noble gas and hyperpolarize the noble gas through a phenomenon known as “spin-exchange.” The “optical pumping” of the alkali metal vapor is produced by irradiating the alkali-metal vapor with circularly polarized light at the wavelength of the first principal resonance for the alkali metal (e.g., 795 nm for Rb). Generally stated, the ground state atoms become excited, then subsequently decay back to the ground state. Under a modest magnetic field (10 Gauss), the cycling of atoms between the ground and excited states can yield nearly 100% polarization of the atoms in a few microseconds. This polarization is generally carried by the lone valence electron characteristics of the alkali metal. In the presence of non-zero nuclear spin noble gases, the alkali-metal vapor atoms can collide with the noble gas atoms in a manner in which the polarization of the valence electrons is transferred to the noble-gas nuclei through a mutual spin flip “spin-exchange.”

Conventionally, lasers have been used to optically pump the alkali metals. Various lasers emit light signals over various wavelength bands. In order to improve the optical pumping process for certain types of lasers (particularly those with broader bandwidth emissions), the absorption or resonance line width of the alkali metal can be made broader to more closely correspond with the particular laser emission bandwidth of the selected laser. This broadening can be achieved by pressure broadening, i.e., by using a buffer gas in the optical pumping chamber. Collisions of the alkali metal vapor with a buffer gas will lead to a broadening of the alkali's absorption bandwidth.

In traditional spin exchange optical pumping (SEOP) constant flow systems, a helium-nitrogen-(¹²⁹) xenon gas mixture flows through the optical cell where the SEOP process occurs. Subsequently, the hyperpolarized ¹²⁹Xe is separated and collected from this gas mixture. Post collection, the ¹²⁹Xe is returned back to a gaseous state which is flowably collected in a dose delivery bag, such as a TEDLAR bag, for administration to patients. For examples of prior cryogenic accumulators, see, e.g., U.S. Pat. Nos. 5,809,801; 6,305,190 and 6,735,977, the contents of which are hereby incorporated by reference as if recited in full herein.

Conventionally, the polarized ¹²⁹Xe is dispensed into a prepared dose delivery bag at an outlet of the manifold of the hyperpolarizer, followed by nitrogen, with the nitrogen added until the bag is sufficiently inflated.

Known systems use syringes with graduated markings, such as increments of 20 mL, to dispense amounts of hyperpolarized gas. However, such systems can have relatively large “dead space” losses and/or a relatively large variability in amounts of the hyperpolarized gas actually dispensed.

There is a need for improved gas dispensing systems.

### SUMMARY

Embodiments of the present invention provide a gas dispensing control system using a gas expansion chamber to measure volumes of gas dispensed to a dose container for medicinal use based in part on measured local atmospheric conditions.

Embodiments of the present invention provide an automated system with a display panel and graphic user interface with defined control inputs and status indicators for various actions associated with a gas control dispensing system particularly suitable for dispensing medical grade hyperpolarized gas or gas mixtures.

Still other aspects are directed to a flow-through spin exchange optical pumping (SEOP) hyperpolarized gas production system for producing hyperpolarized gas that includes: a pressurized gas mixture; a flow-through optical pumping cell in fluid communication with the pressurized gas mixture; and an automated gas dispensing control system with a large volume expansion chamber enclosing a plunger (floatable piston) downstream of and in fluid communication with the flow-through optical pumping cell.

The flow-through SEOP gas production system can further include a flexible patient dose delivery bag downstream of the dispensing system configured to receive an inhalable bolus of hyperpolarized ¹²⁹Xe gas.

Embodiments of the invention are directed to gas dispensing control systems that include: a gas expansion chamber comprising a first end portion, a second end portion opposing and spaced apart from the first end portion, and a plunger in the expansion chamber configured to travel between the first end portion and the second end portion; a first valve coupled to the first end portion of the gas expansion chamber and in fluid communication with a nitrogen gas supply; a second valve coupled to the second end portion of the gas expansion chamber and in fluid communication with the nitrogen gas supply; and a controller in communication with the first valve and the second valve to direct the first valve to be in an open state and the second valve to be in a closed state or direct the second valve to be in an open state and the first valve to be in a closed state so that nitrogen gas from the nitrogen gas supply either: enters the first end portion of the gas expansion chamber or enters the second end portion of the gas expansion chamber.

The gas expansion chamber can have a volume in a range of about 3000 mL to about 4000 mL.

The gas dispensing control system can further include a vacuum pump coupled to an evacuation outlet valve that is in communication with the controller and controllably operated so that the vacuum pump is in fluid communication with the first end portion of the gas expansion chamber or the second end portion of the vacuum chamber whereby spaces inside the gas expansion chamber on opposing sides of the plunger are evacuated at different times.

The gas dispensing control system can further include a Helmholtz coil extending about the gas expansion chamber.

The gas mixture can include hyperpolarized ¹²⁹Xe and the nitrogen, and the controller can be configured to provide a defined ratio of nitrogen to the hyperpolarized ¹²⁹Xe in the gas expansion chamber.

The nitrogen can be ultrahigh purity (UHP) nitrogen.

The gas dispensing control system can further include a pressure sensor adjacent the expansion chamber and in communication with the controller. The controller can be configured to calculate a standard milliliter quantity of gas in the expansion chamber based on one or more measurements of local atmospheric pressure based on data from the pressure sensor.

A temperature sensor may also be coupled to the gas expansion chamber and in communication with the controller and used for gas control operations.

The gas dispensing control system can further include one or more of: a fluid manifold coupled to the gas expansion chamber, the nitrogen gas supply, a gas collection system and a gas dispensing outlet; a vacuum pump coupled to the fluid manifold; an evacuation outlet valve coupled to the fluid manifold adjacent the vacuum pump; a gas dispensing outlet valve upstream of the gas dispensing outlet; a first flow isolation valve positioned at a first position of the fluid manifold upstream of the gas dispensing outlet valve; a second isolation valve spaced apart from the first flow isolation valve and positioned at a second position of the fluid manifold, also upstream of the gas dispensing outlet valve; and a nitrogen outlet flow valve coupled to the fluid manifold between the nitrogen gas supply and the gas expansion chamber.

The evacuation outlet valve, the gas dispensing outlet valve, the first flow isolation valve and the second flow isolation valve can all be in communication with the controller, and the controller can be configured to control sets of respective valves between on and off positions.

The controller can carry out one or more of the following actions: (i) close the nitrogen outlet flow valve, the first isolation flow valve, the second flow isolation valve and the first valve coupled to the gas expansion chamber and open the evacuation outlet valve and the second valve coupled to the gas expansion chamber and pull a first vacuum (optionally about 300 Torr) on a back side of the gas expansion chamber between the plunger and the second end portion of the gas expansion chamber to at least partially retract the plunger; (ii) close the evacuation outlet valve and the second valve coupled to the gas expansion chamber and open the nitrogen outlet flow valve, the first flow isolation valve and the first valve coupled to the gas expansion chamber to flow nitrogen into the gas expansion chamber and pressurize a front side of the gas expansion chamber (optionally to about 35 PSIA) between the plunger and the first end portion of the gas expansion chamber; (iii) close the nitrogen outlet flow valve and the first valve coupled to the gas expansion chamber and open the evacuation outlet valve and the second valve coupled to the gas expansion chamber to pull a second vacuum on the back side of the plunger, with the second vacuum being at a greater vacuum level (optionally about 1 Torr) to retract the plunger to a fully retracted position at the second end portion of the gas expansion chamber; and (iv) with the second valve coupled to the gas expansion chamber open, or direct the second valve to open, and open the first valve coupled to the gas expansion chamber to evacuate both the back side and the front side of the gas evacuation chamber thereby providing a reset status for the gas expansion chamber to thereby be in a state ready to receive gas from the gas collection system.

The gas collection system can be a cryo-collection gas collection system that freezes, then thaws, collected hyperpolarized ¹²⁹Xe. When a cryo-collection accumulation is complete, the controller can be configured to: (v) close the gas dispensing outlet valve, the first isolation valve, the evacuation outlet valve, and the second valve coupled to the gas expansion chamber and open the second flow isolation valve with the first valve coupled to the gas expansion chamber open so that thawed ¹²⁹Xe gas flows into the gas expansion chamber; and (vi) open the first flow isolation valve and the nitrogen outlet flow valve to direct a controlled amount of nitrogen into the gas expansion chamber with the ¹²⁹Xe to form a gas mixture.

The gas dispensing control system can be configured to dispense the gas mixture into a dose bag coupled to the gas dispensing outlet by closing the first isolation flow valve, opening the gas dispensing outlet valve, opening the nitrogen outlet flow valve and the second valve coupled to the gas expansion chamber to pressurize the back side of the plunger and move the plunger toward the first end portion of the gas expansion chamber.

The nitrogen outlet flow valve can be provided as a first nitrogen outlet flow valve and a second nitrogen outlet flow valve. The fluid manifold can include a nitrogen flow path comprising a first nitrogen branch between the nitrogen gas supply and the first nitrogen outlet flow valve and a second nitrogen branch between the second nitrogen outlet flow valve and the nitrogen gas supply. The first nitrogen branch and the second nitrogen branch can merge into a nitrogen feed channel that extends between the second end portion of the gas expansion chamber and the first end portion of the gas expansion chamber.

The plunger can be moved in the gas expansion chamber between first and second opposing directions only by automatically applied pressure directed by the controller to thereby apply pressure to a first side or a second side of the plunger.

The gas dispensing control system can further include one or more of: a nitrogen flow control valve in fluid communication with the nitrogen gas supply; a vacuum pump in fluid communication with the gas expansion chamber; an evacuation outlet valve between the gas expansion chamber and the vacuum pump; a first flow isolation valve; a second flow isolation valve; and a gas dispensing outlet valve. The controller can also be in communication with the gas dispensing outlet valve, the evacuation outlet valve, the first flow isolation valve and the second flow isolation valve.

The gas dispensing control system can further include a fluid manifold coupled to the gas expansion chamber and the nitrogen gas supply. The fluid manifold can have a nitrogen flow path with a first branch with a first branch valve and a second branch with a second branch valve, each downstream of the nitrogen supply and upstream of the gas expansion chamber.

The second branch can have a restricted segment upstream of the second branch valve.

The gas dispensing control system can include a gas outlet path with a gas outlet valve positioned between the first valve and a dispensing outlet coupled to a gas collection container.

The gas expansion chamber can be in fluid communication with a cryo-collection system, and the first valve can be configured to open to flowably receive a quantity of hyperpolarized ¹²⁹Xe gas.

The gas dispensing control system can further include a display providing a user interface for controlling operational components of the gas dispensing control system and visually providing operational status data of the gas dispensing control system.

Other aspects of the invention are directed to a flow-through spin exchange optical pumping (SEOP) hyperpolarized gas production system for producing hyperpolarized gas comprising: a pressurized gas mixture; a flow-through optical pumping cell in fluid communication with the pressurized gas mixture; a cryo-collection system downstream of and in fluid communication with the flow-through optical pumping cell; and a gas dispensing control system with a gas expansion chamber in fluid communication with the SEOP hyperpolarized gas production system.

The flow-through SEOP gas production system can further include a flexible patient dose delivery bag downstream of the gas expansion chamber and coupled to a gas dispensing outlet.

Yet other embodiments are directed to methods of dispensing hyperpolarized ¹²⁹Xe, that include: providing a gas control dispensing system comprising a gas expansion chamber with a plunger in communication with a vacuum pump and a nitrogen supply; directing nitrogen from the nitrogen supply into a first end portion of the gas expansion chamber in front of the plunger; evacuating a back side space of the gas expansion chamber in back of the plunger to further or fully retract the plunger; then evacuating a front side of the gas expansion chamber to place the gas expansion chamber in a ready state for receiving hyperpolarized ¹²⁹Xe gas; then directing hyperpolarized ¹²⁹Xe gas from a gas collection system to flow into the first end portion of the gas expansion chamber; and then directing nitrogen from the nitrogen gas supply to flow into the second end portion of the gas expansion chamber to move the plunger a defined amount to force a defined volume of the ¹²⁹Xe gas or a gas mixture with the ¹²⁹Xe and nitrogen out of the first end portion of the gas expansion chamber and into a container.

The methods can further include: electronically determining local atmospheric pressure; calculating a volume of ¹²⁹Xe gas or a volume of a gas mixture with the ¹²⁹Xe in the expansion gas chamber based on the local atmospheric pressure; and automatically controlling the plunger to move to dispense ¹²⁹Xe based on, at least in part, the calculated volume.

The methods can further include, before directing nitrogen from the nitrogen gas supply to flow into the second end portion of the gas expansion chamber to move the plunger, automatically directing nitrogen from the nitrogen gas supply into the first end portion of the gas expansion chamber to form a gas mixture with a defined ratio of nitrogen to the hyperpolarized ¹²⁹Xe gas in the gas mixture.

The methods can further include allowing a user to controllably alter the defined ratio of nitrogen to ¹²⁹Xe gas to thereby provide different dispensed ratios of the gas mixture into different containers.

As will be appreciated by those of skill in the art in light of the above discussion, the present invention may be embodied as methods, systems and/or computer program products or combinations of same. In addition, it is noted that aspects of the invention described with respect to one embodiment, may be incorporated in a different embodiment although not specifically described relative thereto. That is, all embodiments and/or features of any embodiment can be combined in any way and/or combination for any number of desired activities and/or any degree of activity performance complexity or variability. Applicant reserves the right to change any originally filed claim or file any new claim accordingly, including the right to be able to amend any originally filed claim to depend from and/or incorporate any feature of any other claim although not originally claimed in that manner. These and other objects and/or aspects of the present invention are explained in detail in the specification set forth below.

The foregoing and other objects and aspects of the present invention are explained in detail herein.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Other features of the present invention will be more readily understood from the following detailed description of exemplary embodiments thereof when read in conjunction with the accompanying drawings.

FIG. 1 is a schematic illustration of a hyperpolarizer incorporating an automated gas dispensing control system with a gas expansion chamber according to embodiments of the present invention.

FIG. 2 is a schematic illustration of a hyperpolarizer with a gas dispensing control system with the gas expansion chamber according to embodiments of the present invention.

FIG. 3 is top side perspective view of an example gas expansion chamber according to embodiments of the present invention.

FIG. 4 is a bottom, side perspective view of the device shown in FIG. 3.

FIG. 5A is a side view of the device shown in FIG. 3

FIG. 5B is a partially exploded view of the device shown in FIG. 3.

FIG. 6 is a side perspective view of the device shown in FIG. 3 and shown positioned inside Helmholtz coils with a support wall providing an outlet to a dose container also positioned inside the Helmholtz coils according to embodiments of the present invention.

FIG. 7 is a flow chart of example actions for a freeze/thaw process according to embodiments of the present invention.

FIGS. 8-10 are images of a series of displays providing example graphic user interface of a display panel with a graphic user interface with defined control inputs and status indicators for various actions associated with a gas control dispensing system particularly suitable for dispensing medical grade hyperpolarized gas or gas mixtures according to embodiments of the present invention.

FIG. 11 is a schematic of a data processing system with a gas dispensing control module according to embodiments of the present invention.

### DETAILED DESCRIPTION

The present invention will now be described more fully hereinafter with reference to the accompanying figures, in which preferred embodiments of the invention are shown. This invention may, however, be embodied in many different forms and should not be construed as limited to the embodiments set forth herein.

Like numbers refer to like elements throughout. In the figures, layers, regions and/or components may be exaggerated for clarity. The word “Figure” is used interchangeably with the abbreviated forms “FIG.” and “FIG.” in the text and/or drawings. Broken lines illustrate optional features or operations unless specified otherwise. In the description of the present invention that follows, certain terms are employed to refer to the positional relationship of certain structures relative to other structures.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

It will also be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention. The sequence of operations (or steps) is not limited to the order presented in the claims or figures unless specifically indicated otherwise.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the data or information in use or operation in addition to the orientation depicted in the figures. For example, if data in a window view of the system in the figures is inverted, elements described as “under” or “beneath” other elements or features would then be oriented “over” the other elements or features. Thus, the exemplary term “under” can encompass both an orientation of over and under. The display view may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

As used herein, the term “forward” and derivatives thereof refer to the general direction a noble gas mixture travels as it moves through the hyperpolarizer system; this term is meant to be synonymous with the term “downstream” which is often used in manufacturing environments to indicate that certain material being acted upon is farther along in the manufacturing process than other material. Conversely, the terms “rearward” and “upstream” and derivatives thereof refer to the directions opposite, respectively, the forward and downstream directions.

Also, as described herein, target gases such as polarized gases can be collected, frozen, then thawed, and used. Polarized/hyperpolarized noble gases can be used in MRI applications. For ease of description, the term “frozen gas” means that the gas has been frozen into a solid state. The term “liquid gas” means that the frozen gas has been or is being liquefied into a liquid state. The term “gas” alone refers to the gaseous state. Thus, although each term includes the word “gas”, this word, used with a state modifier is used to name and descriptively track the gas which is produced. For hyperpolarized/polarized gas, it is produced via a hyperpolarizer to obtain a polarized/hyperpolarized “gas” product. Therefore, as used herein, the term gas has been used in certain places to descriptively indicate a hyperpolarized noble gas product and may be used with modifiers such as solid, frozen, and liquid to describe the state or phase of that product. Although the below description is primarily described with respect to a hyperpolarized noble gas, such as ¹²⁹Xe, the devices can be used to dispense other gases, particularly in successive relatively small quantities, such as under about 2 liters.

In some embodiments, the polarized ¹²⁹Xe gas can be produced and formulated to be suitable for internal (inhalable) pharmaceutical human or animal medical purposes.

The term “about” means within plus or minus 10% of a recited number.

The term “polarization friendly” means that the device is configured and formed of materials and/or chemicals that do not induce or cause more than di minimis decay (e.g., less than about 2%) of the polarization of the polarized noble gas, e.g., ¹²⁹Xe.

The term “compact” with respect to optical pumping cells, refers to optical pumping cells that are between about 50 cubic centimeters (“ccs”) to about 1000 ccs, typically between about 100 ccs and 500 ccs, in volumetric capacity.

The term “high volume” means that the polarizer is a continuous flow polarizer (or at least substantially continuous), once activated for production for a given supply of gas mixture to produce at least between about 1.5 ccs to about 500 cc's of polarized noble gas per minute, and/or between about 1000 cc's to about 10,000 cc's, or even more, per hour. The terms “polarizer” and“hyperpolarizer” are used interchangeably herein.

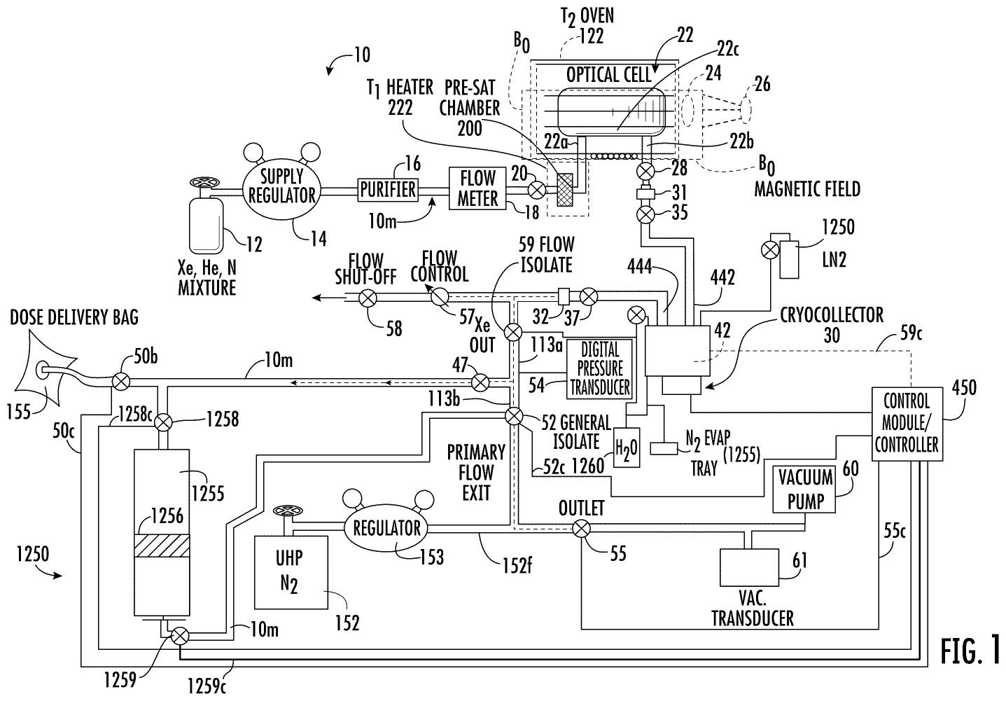

With reference to FIG. 1, an example hyperpolarizer 10 is shown. The hyperpolarizer 10 includes as fluid manifold 10m, an optical pumping cell 22 upstream of a cryo-collection system 30 and a gas dispensing control system 1250 downstream of the cryo-collection system 30. A control module 450 comprising at least one processor can be coupled to the cryo-collection system 30 and the gas dispensing control system 1250 to electronically control operation thereof. Although shown as a single control system 450, separate control systems may be used. Commercial hyperpolarizers comprising gas handling manifolds, a xenon polarizer and supporting devices are available from Polarean, Inc., Durham, North Carolina. Additional components of the hyperpolarizer 10 shown in FIG. 1 will be discussed below.

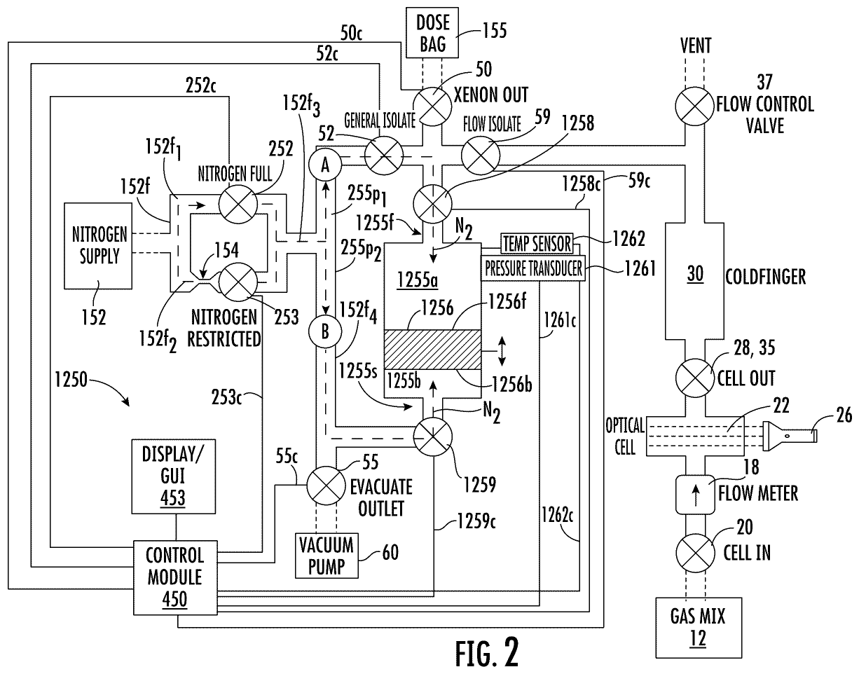

FIG. 2 illustrates the gas dispensing control system 1250 downstream of the cryo-collection system 30. The gas dispensing control system 1250 comprises a gas expansion chamber 1255 with an internal plunger 1256. The plunger 1256 can also be referred to as a “piston” or “floatable piston” as the plunger/piston 1256 moves between opposing front and back directions based on pressure applied to either a front side 1256f or a back side 1256b of the plunger 1256. No external rod coupled to the plunger 1256 is required. This configuration is an example embodiment of such a system and other configurations are contemplated for the gas expansion chamber 1255, the piston therein 1256, the manifold plumbing 10m, valve layout and controls, for example. This embodiment allows for a completely sealed chamber as the plunger piston 1256 (which can also be referred to interchangeably as a “puck”) can be actuated with compressed nitrogen rather than by mechanical drive.

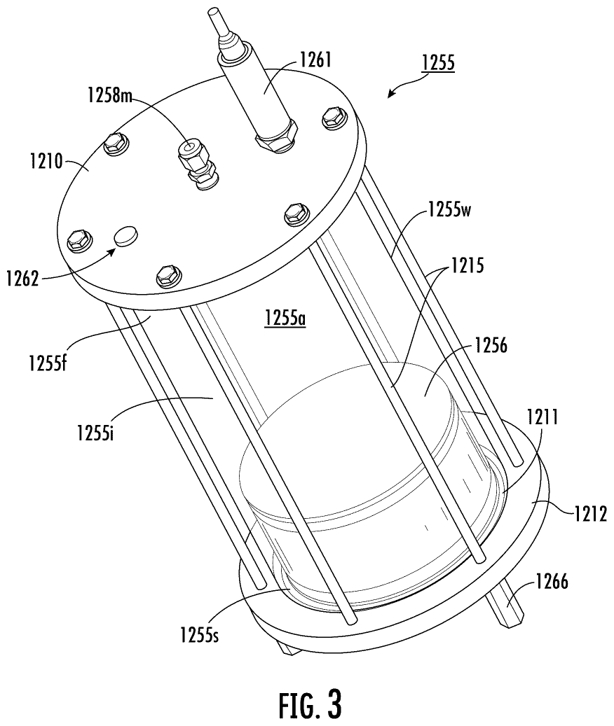

Embodiments of the invention provide a gas dispensing control system 1250 that can provide automated volumetry, blending and dispensing of (laser-polarized noble) gases. The gas dispensing control system 1250 can be configured to measure hyperpolarized ¹²⁹Xe gas produced by a hyperpolarizer system 10. The blending of nitrogen with the hyperpolarized ¹²⁹Xe gas can be carried out for subsequent dispensing into a dose delivery container such as a dose delivery bag 155 comprising one or more bolus of the gas/gas mixture. In this gas dispensing control system 1250, a volume of gas is determined using absolute pressure measurements from a high precision pressure gauge 1261 (FIG. 2), and a known volume of the gas exchange chamber 1255 having a piston 1256 for dispensing the gas/gas mixture to the dose container 155, such as a bag or other container type. The gas dispensing control system 1250 can also comprise a temperature sensor 1262 (FIGS. 2, 3). The pressure gauge 1261 and the temperature sensor 1262 can be mounted in the top plate/lid 1210 as shown in FIG. 3. However, other locations can be used for placing the pressure gauge and temperature sensor, 1261, 1262, respectively.

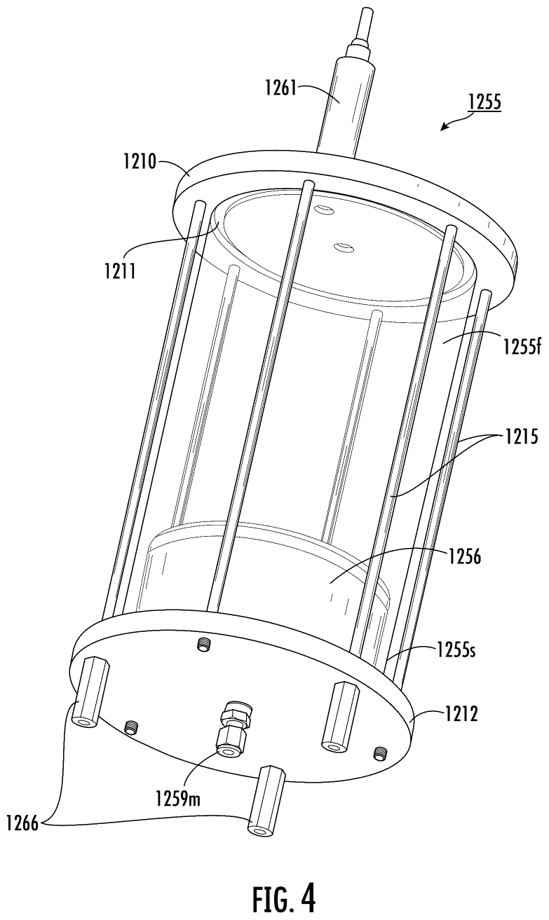

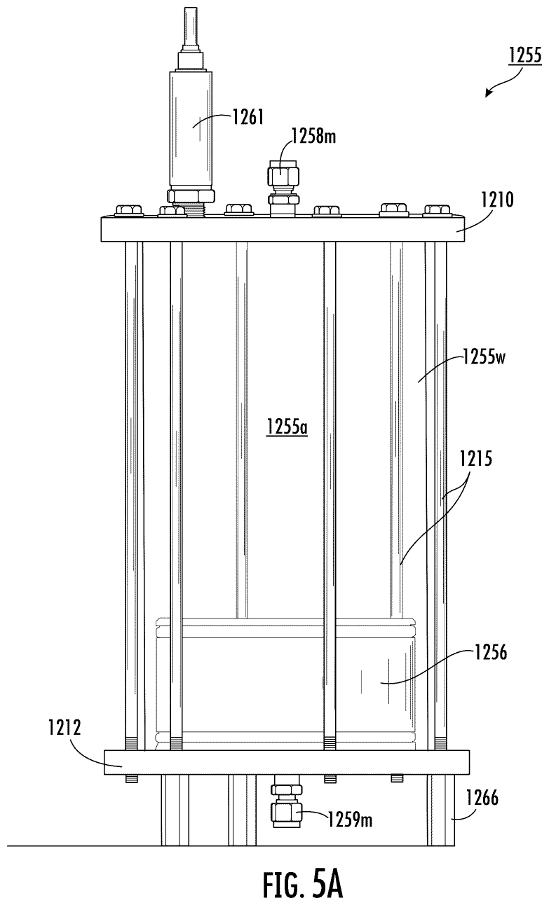

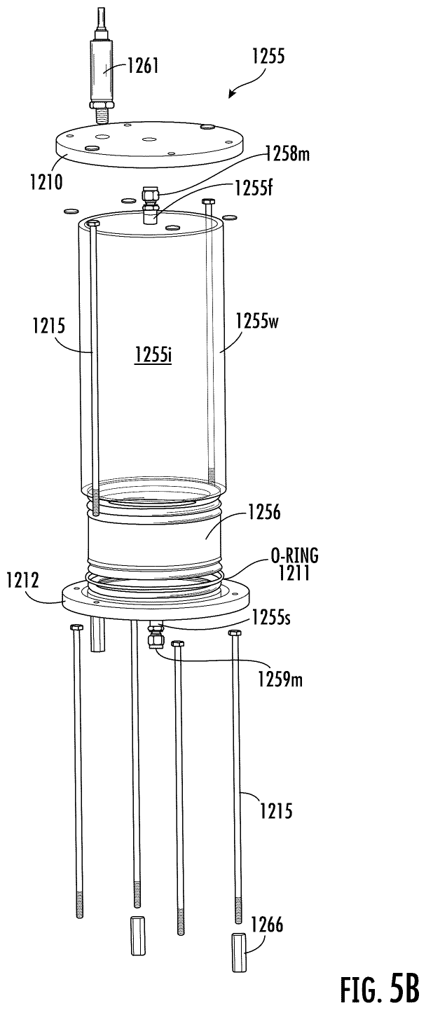

Referring to FIGS. 2-6, the gas expansion chamber 1255 has a first end portion 1255f and an opposing second end portion 1255_{S} and an internal chamber 1255i configured to allow the piston 1256 to (controllably) move bidirectionally. The gas expansion chamber 1255 may be oriented so that the first end portion 1255f is at the top and the second end portion 1255_{S} is at the bottom but other orientations may be used. For example, the gas expansion chamber 1255 may be oriented at 90 degrees from that shown so that the first end portion 1255f is at a first side end and the second end portion 1255_{S} is at an opposing side end (not shown). Non-vertical, non-horizontal orientations may also be used.

The gas expansion chamber 1255 can have a large volume that is at least twice a volume of a bolus amount of gas/gas mixture for a particular dispensing action. The large volume can be in a range of 3000-4000 mL, such as about 3100 mL in some embodiments.

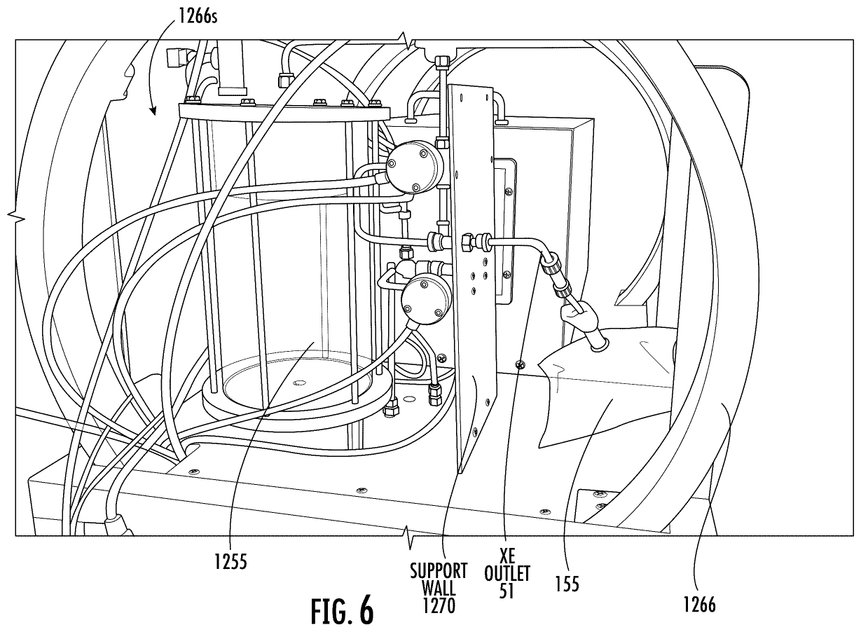

FIG. 6 shows the gas expansion chamber 1255 inside a space 1266s provided by Helmholtz coils 1266. A support wall 1270 can also reside inside the space 1266s as can the dispensing outlet 51 that is downstream of the gas expansion chamber 1255 along with one or more serially fillable respective dose containers 155 for filling/dispensing with the gas mixture from the gas expansion chamber 1255.

The gas expansion chamber 1255 is in fluid communication with the gas manifold 10m. Various valves are used to control flow of nitrogen and hyperpolarized noble gas into and out of the gas expansion chamber 1255 and to be able to evacuate both sides of the gas expansion chamber 1255, the side/space 1255a in front of the front side 1256f of the plunger 1256 and the side/space 1255b behind the back side 1256b of the plunger 1256.

A first valve 1258 is in fluid communication with and/or coupled to the first end portion 1255f and a second valve 1259 is in fluid communication with and/or coupled to a second end portion 1255_{S} of the gas expansion chamber 1255.

The gas dispensing control system 10 can also include the following valves spaced apart and coupled to the gas manifold 10m. As shown, the gas manifold 10m comprises a first gas isolation valve 52, a second gas isolation valve 59, a gas dispensing outlet valve 50, and an evacuation outlet valve 55 upstream and adjacent a vacuum pump 60.

As is also shown, at least one nitrogen flow control valve 252 (shown as two separate nitrogen flow control valves 252, 253) can be positioned between the UHP (ultrahigh purity) nitrogen gas supply 152 and the gas expansion chamber 1255 to control nitrogen flow to the gas expansion chamber 1255, and the first isolation valve 52 and the first and second valves 1258, 1259 coupled to the gas expansion chamber 1255 can be operated to direct nitrogen gas into the first end portion 1255f of the gas expansion chamber 1250 or the second end portion 1255s.

Referring to FIGS. 1 and 2, each valve can be in communication with one or more controllers 450 and may have a blue tooth or other control link or coupling shown by the “c” added to the respective callout; e.g., 50c, 52c, 55c, 59c, 252c, 253c, 1258c, 1259c, providing the control communication to allow the one or more controller(s) 450 to direct a sequence of open and close states of each valve to carry out a reset, a gas chamber intake/fill and a dispensing (out of the gas expansion chamber) action using the gas expansion chamber 1255.

The gas expansion chamber 1255 does not require graduated measurement markings as the volume of gas therein is measured based on ideal gas laws using a measurement of local atmospheric pressure. The volume measurement can be generated using an onboard pressure sensor 1261 that can be in communication with the controller 450 using a control link or coupling 1261c.

The gas manifold 10m comprises a nitrogen flow path 152f extending from the nitrogen gas supply 152 that comprises a first branch segment 152f₁ and a second branch segment 152f₂ that can optionally merge together downstream of respective valves 252, 253 to then merge into a short, third nitrogen flow path segment 152f₃ that branches into a fourth nitrogen branch 152f₄ that is longer than the third flow path segment 152f₃ and that extends between the first end portion 1255f of the gas expansion chamber 1255 and the second end portion 1255_{S} of the gas expansion chamber 1255.

The second branch segment 152f₂ can comprise a restricted segment 154 upstream of the second branch valve 252. This allows a more precise delivery of nitrogen to the gas expansion chamber 1255 for providing part of the gas mixture for dispensing. The non-restricted first branch 152f₁ can be used to push the piston 1256. The valves 252, 253 can be two-way (open and close) valves.

FIGS. 3-5B show an example gas expansion chamber 1255. In this embodiment, a pair of plates 1210, 1212 are sealably attached to a cylindrical chamber wall 1255w via seal members 1211. The seal members 1211 can be any suitable type such as gaskets, O-rings or even vacuum grease or combinations of same. Circumferentially spaced apart and longitudinally extending attachment legs 1215 can be used to secure the cylindrical chamber wall 1255w and the plates 1210, 1212 and can force the plates 1210, 1212 to clamp together to form a seal tight coupling.

The pressure gauge 1261 can be coupled to one of the plates, shown as the first plate 1210, to be in fluid communication with the chamber 1255. Valve couplings 1258m, 1259m can extend outside a respective plate 1210, 1212. The second plate 1212 may also comprise standoffs 1266.

In example actions, in order to reset the gas expansion chamber 1255, the evacuate outlet valve 55 and the second chamber valve 1259 are opened and a crude/rough vacuum (for example, about ˜300 Torr) can be pulled on the backside of the chamber 1255 (below the piston in the orientation shown).

The evacuate outlet valve 55 and the second (bottom) chamber valve 1259 are closed and the nitrogen full 252, the first (general isolate) isolation valve 52, and the first (top) chamber valve 1258 are opened to pressurize the topside (˜35PSIA) and move the plunger 1256 down.

The nitrogen full valve 252 and first (top) chamber valve 1258 are closed before the evacuate outlet 55 and the second (bottom) chamber valve 1259 are opened once again. This time a higher vacuum level (˜1 Torr) is pulled on the backside to ensure the plunger is in a fully retracted position.

The first (top) chamber valve 1258 is then opened to evacuate the topside. When cryo-collection is complete, the xenon out valve 50, the first (General Isolate) isolation valve 52, the second (bottom) chamber valve 1259, and the evacuate outlet valve 55 are closed. The second (Flow Isolate) flow isolation valve 59 is opened and the xenon is thawed, returning it to a gaseous state and allowing it to flow into and at least partially fill the gas expansion chamber 1255.

The second (Flow Isolate) isolation valve 59 is closed. With the known gas expansion chamber dimensions and chamber pressure the standard volume of xenon captured can be determined.

Nitrogen may then be added to the gas expansion chamber 1255 depending on a desired dose mixture. This is done by opening the first flow isolation valve 52 (General Isolate) and either the first nitrogen flow valve 252 (Nitrogen Full) or the second nitrogen flow valve 253 (Nitrogen Restricted).

As discussed above, the second nitrogen flow valve 253 for the restricted flow segment 154 allows for better control in adding the desired amount of nitrogen.

To dispense the gas/gas mixture into the dose container 155, the first (General Isolate) isolation valve 52 is closed and the xenon out 50 valve is opened. The nitrogen flow control valve 252 and the second (bottom) chamber valve 1259 are then opened to pressurize the backside and move the plunger 1256 up.

It is noted that although the gas control dispensing system 1250 is shown using a single supply of nitrogen 152 to provide a component of a gas mixture and to push the piston 1256, separate nitrogen gas supplies may be used.

Also, the gas used to push the piston 1256 to dispense the gas/gas mixture out of the gas expansion chamber 1255 may be provided by other pressurized gas/gas mixture and is not required to be nitrogen. To retract the plunger/piston 1256, the topside is typically pressurized. Using a gas other than what goes into the final gas mixture could leave contamination behind so care should be taken if using a different gas supply. In addition, a separate vacuum may be used to avoid possible contamination of the chamber content.

Another example process flow sequence is described below.

### Example Process Flow

1. Dose delivery bag 155 is attached to “Xe Out” 51 (FIG. 6).
2. Dose delivery bag 155 can be prepared by alternately opening the combination of “Xe Out” valve 50, “Evac. Outlet” valve 55, and “Gen. Iso” valve 52, and the combination of “Xe Out” valve 50, “Purge Outlet” valve 255, and “Gen. Iso.” Valve 52 finishing with the first combination.
3. All gas dispensing control system valves are closed
4. Piston 1256 is reset
a. The lower chamber valve 1259 is open along with the “Evac Outlet” valve 55
b. When there is a sufficient vacuum achieved, the valve 1259 is closed and the upper chamber valve 1258, “Gen. Iso.” Valve 52 and “Purge Outlet” valve 55 are opened.
c. The piston 1256 moves to the bottom 1255b of the cylinder 1255.
5. All valves are closed
6. The upper chamber valve 1258, “Gen. Iso.” Valve 52 and “Evac Outlet” valve 55 are opened, and a vacuum is pulled.
7. When a good vacuum is achieved, the lower chamber valve 1259 and “Xe Out” valve 50 are opened, and a vacuum is continued to be pulled until such a time as a measurement is required.
8. Xenon measurement
a. The “Gen. Iso.” 52 and “Vac. Outlet” 55 valves are closed
b. Xenon to be measured is introduced through the upper cylinder valve 1258 and via the “Flow Iso.” Valve 59 typically via the thawing of collected xenon.
c. When the pressure in the chamber 1255 has equilibrated, the volume of xenon at atmosphere (V_{A}) is determined via V_{A}=P_{c}/P_{A}V_{c} where P_{c} is the measured chamber pressure, P_{A}is atmospheric pressure and V_{C} is the chamber volume.
d. All valves are closed
9. Nitrogen addition
a. Nitrogen is introduced through the upper cylinder valve 1258 and via the restricted flow “Purge Outlet” valve 253.
b. When the pressure in the chamber 1255 has reached the pressure P_{c}=V_{A}/V_{c}P_{A} where V_{A}is the required volume of mixed gas at atmosphere (typically 1 L), P_{A} is atmospheric pressure and Vₑ is the chamber volume.
c. All valves are closed
10. Gas Dispense
a. The Xe Out valve 50 and upper cylinder valve 1258 are opened.
b. The “Purge Outlet” 252 and lower cylinder valves 1259 are opened.
c. The piston 1256 is forced upward by the nitrogen under the piston 1256 and the xenon gas mixture is dispensed into the dose delivery container/bag 155.

Referring again to FIG. 1, the cryo-collection system 30 can be any suitable system, typically using one or more coldfingers to freeze, then thaw collected ¹²⁹Xe gas from a gas mixture downstream of an optical pumping cell 22 (FIG. 1). Examples are provided in co-pending U.S. Provisional Patent Application Ser. Nos. 63/484,044 and 63/484,078, the contents of which are hereby incorporated by reference as if recited in full herein.

During collection/accumulation/freeze of the ¹²⁹Xe, the cooler 340 can provide a temperature in a range of 77K to 165K, typically in a range of 77K to 103K, more typically in a range of 77K-80K, at the end portion 342e of the cold finger 342. A typical single bolus of ¹²⁹Xe for inhalation can be in a range of 250 mL to 750 mL. The accumulator 42 can be configured to collect the bolus amounts or multiple bolus amounts (which can be subsequently divided into different dose delivery containers) and may have a maximum capacity of 1-1.5 liters (gaseous state), in some embodiments.

Flow rates (for the gas mixture) in the cryo-collection system 30 can typically be from 1SLM to 5SLM with the collection time depending completely on the quantity desired to be collected. For a 1 L collection, this collection time is about 100 minutes for 1 SLM (Standard Liter per Minute), 50 minutes for 2 SLM, 33 minutes for 3 SLM, 25 minutes for 4 SLM, and 20 minutes for 5 SLM.

The amount of ¹²⁹Xe provided to the gas expansion chamber 1255 may vary freeze/thaw cycle to freeze/thaw cycle.

It is noted that, the present invention is not limited to any particular (hyper) polarizer configuration, embodiments of the invention are particularly suitable for high-volume, flow polarizer systems. These systems can take on various forms and use various components as is known to those of skill in the art. To be clear, different components and arrangements may be used and not all components shown are required.

Thus, referring again to FIG. 1, as is known by those of skill in the art, this figure illustrates an example of a modified compact flow-through high volume hyperpolarizer which is configured to (continually over a production run) produce and accumulate spin-polarized noble gases, i.e., the flow of gas through the unit is substantially continuous. As shown, the hyperpolarizer unit 10 includes a noble gas (¹²⁹Xe) supply 12 and a supply regulator 14. A purifier 16 can be positioned in the line to remove impurities such as water vapor from the system as will be discussed further below. The hyperpolarizer 10 can also include a flow meter 18 and an inlet valve 20 positioned upstream of the optical (polarizer) cell 22, typically also upstream of the pre-saturation (“pre-sat”) chamber 200. An optic light source such as a laser 26 (either narrow or broad band, typically a diode laser array) is directed into the polarizer cell 22 through various focusing and light distributing means 24, such as lenses, mirrors, and the like. The light source is circularly polarized to optically pump the alkali metals in the cell 22. An additional valve 28 can be positioned downstream of the polarizer cell 22.

Next in line, is the cryo-collection system 30. The cryo-collection system 30 can be connected to the hyperpolarizer 10 by a pair of releasable mechanisms such as threaded members or quick disconnects 31, 32. This allows the cryo-collection system 30 to be easily detached, removed, or added, to and from the system 10.

A vacuum pump 60 is in fluid communication with the system 10 and may be in communication with a vacuum transducer 61. Additional valves to control flow and direct exit gas can be used and are shown at various points (shown as 52, 55). A shut-off valve 47 can be positioned adjacent, upstream of adjacent an “on-board” exit gas tap at valve 50. Certain of the valves downstream of the cryo-collector 30 can be used for “on-board” thawing and delivery of the collected polarized gas. The system 10 can also include a digital pressure transducer 54 and a flow control device 57 along with a shut-off valve 58. The shut-off valve 58 can control the flow of gas through the entire system or unit 10 and can be used to turn the gas flow on and off. As will be understood by those of skill in the art, other flow control mechanisms, devices (analog and electronic) may be used within the scope of the present invention.

In operation, a gas mixture is introduced into the system at the gas source 12. As shown in FIG. 1, the gas source 12 is a pressurized gas tank which holds a pre-mixed gas mixture. The gas mixture includes a lean noble gas (the gas to be hyperpolarized) and buffer gas mixture. Preferably, for producing hyperpolarized ¹²⁹Xe, the pre-mixed gas mixture is about 90% He, about 5% or less ¹²⁹Xe (typically about 1% ¹²⁹Xe), and about 10% N₂. The gas mixture can be passed through the purifier 16 and introduced into the optical (polarizer) cell 22. The valves 20, 28 are on/off valves operably associated with the polarizer cell 22. The gas regulator 14 steps down the pressure from the gas tank source 12 (typically operating at 2000 psi or 136 atm) to about 1-10 atm for the system, e.g., about 1 atm, about 2 atm, about 3 atm, about 4 atm, about 5 atm, or between about 6-10 atm for the system. For systems with spectrally narrowed lasers, lower cell operating pressures of between about 1-3 atm may be particularly desirable.

Thus, during accumulation, the entire manifold 10m (conduit, polarized cell, accumulator, etc.) can be pressurized to the cell pressure (e.g., about 3 atm). The flow in the unit 10 can be activated by opening valve 58 and is controlled by adjusting the flow control means 57. The typical residence time of the gas mixture in the optical cell 22 is about 10-30 seconds, i.e., it takes on the order of 10-30 seconds for the gas mixture to be hyperpolarized while moving through the cell 22.

The gas mixture is typically introduced into the cell 22 at a pressure of between about 1-3 atm and this pressure is about the same as that at the accumulator of the cryo-collector 30.

Of course, with hardware capable of operating at increased pressures, operating pressures of above 10 atm, such as about 20-30 atm can pressure broaden the Rb and absorb up to 100% of the optical light. In contrast, for laser linewidths less than conventional linewidths, lower pressures can be employed. The polarizer cell 22 can be a high-pressure optical pumping cell housed in a heated chamber with apertures configured to allow entry of the laser emitted light.

As noted above, various techniques have been employed to accumulate and capture polarized gases for use in MRI imaging of patients. For example, U.S. Pat. No. 5,642,625 to Cates et al., describes a high volume hyperpolarizer for spin polarized noble gas and U.S. Pat. Nos. 5,860,295; 5,809,801; 6,305,190; and 6,735,977 describe cryogenic accumulators for spin-polarized ¹²⁹Xe. These references are hereby incorporated by reference as if recited in full herein. As used herein, the terms “hyperpolarize” and “polarize” and the like, mean to artificially enhance the polarization of certain noble gas nuclei over the natural or equilibrium levels. Such an increase is desirable because it allows stronger imaging signals corresponding to better MRI images of the substance and a targeted area of the body. As is known by those of skill in the art, hyperpolarization can be induced by spin-exchange with an optically pumped alkali-metal vapor or alternatively by metastability exchange. See Albert et al., U.S. Pat. No. 5,545,396, which is incorporated by reference as if recited in full herein.

Turning again to FIG. 1, an example hyperpolarizer 10 is shown that may include at least one pre-saturation chamber 200. The chamber 200 can be relatively compact and can reside adjacent the entry port of the optical pumping cell 22. The polarizer 10 can include other components as is known by those of skill in the art (and are described below). The term “chamber” with respect to the pre-sat member and/or section of the gas flow path, refers to a region of a flow path that flowably supplies noble gas mixture into the optical pumping cell 22 with vaporized alkali metal. Thus, the pre-sat chamber 200 is configured to house alkali metal that is vaporized and introduced into a flowing noble gas mixture, then into the optical pumping cell 22. The pre-sat chamber 200 can be a detachable component or an integral part of the flow path. The pre-sat chamber 200 can have an Area Ratio of surface area to cross-sectional area that is between 20 and 500, more typically between 20 and 200 as will be discussed below.

In some embodiments, the chamber 200 can be tubular and have a short length such as about between about 0.5 inches to about 2 inches, typically about 1.25 inches.

Optionally, the optical pumping cell 22 can include pairs of conduit legs 22a, 22b that extend to valves, e.g., 20, 28 (which are typically KONTES valves).

The optical pumping cell 22 can be relatively compact with a volume capacity of between about 100 cc to about 500 cc, such as about 100 cc, about 200 cc, about 300 cc, about 400 cc and about 500cc. The optical pumping cell 22 can also have larger sizes, such as between about 500cc-1000 cc, for example. The chamber 200 can have a length L that is between about 0.5 inches to 6 inches long, typically between about 1-3 inches, such as about 1.25″ long. The chamber 200 can have a primary body segment with a cross-sectional height W (e.g., diameter, when tubular) that can be between about 0.25 inches to about 1 inch across, typically about 0.5″.

The pre-sat chamber 200 can contain between about 0.25 grams to about 5 grams of Rb, typically between about 0.5 to about 1 gram of Rb, (measured “new” as shipped by an OEM or supplier and/or prior to a first use).

As shown in FIG. 1, the hyperpolarizer 10 can comprise at least two different temperature-controlled zones T1, T2, one (T1) for the pre-saturation chamber 200 and at least one other (T2) for the optical pumping cell 22 so that T1>T2. The volume of the pre-saturation chamber V1 is also less than the volume V2 of the optical pumping cell 22.

In some embodiments, the pre-saturation chamber 200 in the T1 zone can be heated to temperatures between about 140 degrees C. and 300 degrees C., more typically between about 140 degrees Celsius to about 250 degrees Celsius, such as 140 degrees C., 150 degrees C., 160 degrees C., 170 degrees C., 180 degrees C., 190 degrees C., 200 degrees C., 210 degrees C., 220 degrees C., 230 degrees C., 240 degrees C. and 250 degrees C. The second temperature zone (T2) for the optical pumping cell 22 can be configured to have a temperature that is less than T1, typically with a temperature between about 70 degrees C. to about 200 degrees C., more typically between about 90 degrees C. to about 150 degrees C., such as about 95 degrees C., about 100 degrees C., about 110 degrees C., about 120 degrees C., about 140 degrees C. and about 150 degrees C., to maintain vapor pressure, in some embodiments. The zone T2 may also be configured to apply a temperature gradient of decreasing temperature from a greater temperature at a region proximate the inlet to a lower temperature proximate the exit, typically with a change that is about 10 degrees C., about 15 degrees C., about 20 degrees C., about 25 degrees C. or about 30 degrees C., for example.

The temperature zone T1 can comprise at least one (pre) heater 222 that can provide the desired heat to increase the temperature including conductive and/or convection heaters. The at least one heater 222 can be an electric heater. The at least one heater 222 can comprise one or more of an oven, infrared heaters, resistive heaters, ceramic heaters, heat lamps, heat guns, laser heaters, heat blankets (e.g., heat blanket that can be wrapped about the chamber 200 with at least one insulation layer, typically comprising Nomex®-fiberglass fibers, but other insulation materials may be used), pressurized hot fluid spray and the like. The at least one heater 222 can employ a plurality of different heater types. The at least one heater 222 can comprise an oven that encases or partially encases the chamber 200. The at least one heater 222 can comprise an internal heater in the chamber 200. The temperature zone T2 can also comprise at least one heater 122, typically comprising an oven. Each zone can be independently controlled to maintain a desired temperature or temperatures.

The hyperpolarizer 10 can be configured so that alkali metal is loaded only into the pre-saturation chamber 200 that is outside of the pumping laser exposure region of the cell 22.

The optical (pumping) cell 22 can be mounted to a vacuum manifold and the alkali metal A (e.g., Rb) can be “chased” into the pre-saturation chamber 200. The optical cell 22 can then be operated in a modified conventional high-volume hyperpolarizer 10 where heat is applied primarily to the pre-saturation chamber 200 and to a lesser (cooler degree) to the optical cell 22.

In some particular embodiments, in contrast to a normal optical pumping cell 22 maintained at between 160-180 degrees C., the optical pumping cell 22 can be held at a primary body temperature that is maintained at 150 degrees C. or less, such as between 100 degrees C. and 150 degrees C., including, for example, about 100 degrees C., about 110 degrees C., about 120 degrees C., about 130 degrees C., about 140 degrees C., while Rb saturated vapor is picked up by the flowing gas stream in the pre-saturation chamber 200, which can be maintained at temperatures ranging from between about 150 to 250 degrees C., depending on the desired flow rates. In some particular embodiments, the pre-sat chamber 200 can be held at between 150 degrees C. to about 160 degrees C.

In some embodiments, the hyperpolarizer 10 employs the optical pumping cell 22 at a pressure of about 3 atm. It is contemplated that a spectrally narrowed laser, that has been detuned by about 0.25-0.50 nm from the alkali D1 resonance at that pressure. As will be understood by one of skill in the art, a small pressure shift in resonance occurs from vacuum to the 3 atm pressure which can depend on the buffer gas composition. For example, in vacuum, Rb D1 resonance is at 794.8 nm, whereas at 3 atm with the same buffer gas mixture, it is shifted to a slightly lower wavelength of 794.96 nm.

The hyperpolarizer 10 can employ helium buffer gas to pressure broaden the Rb vapor absorption bandwidth. The selection of a buffer gas can be important because the buffer gas—while broadening the absorption bandwidth—can also undesirably impact the alkali metal-noble gas spin-exchange by potentially introducing an angular momentum loss of the alkali metal to the buffer gas rather than to the noble gas as desired.

Hyperpolarized gas, together with the buffer gas mixture, exits the optical (pumping/polarizer) cell 22 and travels along the manifold (e.g., conduit), then enters the cryo-collection system 30. In operation, the hyperpolarized ¹²⁹Xe gas is exposed to temperatures below its freezing point and collected as a frozen product in the cryo-collector 30. The remainder of the gas mixture remains gaseous and exits through an outlet/exit conduit. The hyperpolarized gas is collected (as well as stored, transported, and preferably thawed) in the presence of a magnetic field. The magnetic field can be provided by permanent magnets positioned about a magnetic yoke. Once a desired amount of hyperpolarized gas has been collected, valve 35 can be closed. The manifold of the hyperpolarizer 10 downstream of the valve 28 can be allowed to depressurize to about 1.5 atm before the flow valve 58 is closed. After closing the flow valve 58, valves 52 and 55 can be opened to evacuate the remaining gas in the manifold. Once the outlet plumbing is evacuated, the second isolation valve 59 is closed and a receptacle/container such as a bag or other vessel 155 can be attached to the outlet 50. Valves 47, 50, 52 and 55 can be opened to evacuate the attached bag 155.

Alternatively, in some embodiments, the manifold 10m can be configured to pull a vacuum on the bag (or vessel into which to ¹²⁹Xe is to be expanded) during the entire collection time. In this case, the second flow isolation valve 59 is closed during flow, and valves 47, 50, 52 and 55 are open. In this configuration, the valves 52 and 55 are closed during the thaw so that thawed ¹²⁹Xe gas is not lost to the vacuum pump.

If the first isolation valve 52 is not closed, then evacuation outlet valve 55 is preferably closed to prevent the evacuation of polarized thawed gases. The flow channels on the downstream side of the cell 22 can be formed from materials which minimize the decaying effect on the polarized state of the gas. Coatings can also be used such as those described in U.S. Pat. No. 5,612,103, the disclosure of which is hereby incorporated by reference as if recited in full herein. In the “on-board” thaw operation, valve(s) 37 in the exit flow path is opened to let the gas out. It then proceeds through valve 47 to outlet 50.

Examples of suitable isolation valves 35, 37 and/or for valves V for the pre-sat chamber 200 (FIG. 1), include Swagelok valves or KIMBLE KONTES valves.

In some embodiments, the valves 35, 37 are in communication with the primary flow channel and the (buffer gas) exit/outlet channel 444, respectively, and each can adjust the amount of flow therethrough as well as close the respective paths to isolate the accumulator from the system 10 and the environment.

As will be appreciated by one of skill in the art, embodiments of the invention may be embodied as a method, system, data processing system, or computer program product. Accordingly, the present invention may take the form of an entirely software embodiment or an embodiment combining software and hardware aspects, all generally referred to herein as a “circuit” or “module.” Furthermore, the present invention may take the form of a computer program product on a non-transient computer usable storage medium having computer usable program code embodied in the medium. Any suitable computer readable medium may be utilized including hard disks, CD-ROMs, optical storage devices, a transmission media such as those supporting the Internet or an intranet, or magnetic or other electronic storage devices.

Computer program code for carrying out operations of the present invention may be written in an object-oriented programming language such as Java, Smalltalk, PYTHON, C# or C++. However, the computer program code for carrying out operations of the present invention may also be written in conventional procedural programming languages, such as the “C” programming language or in a visually oriented programming environment, such as LabVIEW or Visual Basic.

Certain or all aspects of the program code may execute entirely on one or more of a user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider). Typically, some program code executes on at least one web (hub) server and some may execute on at least one web client and with communication between the server(s) and clients using the Internet. The polarizer control systems can be provided using cloud computing which includes the provision of computational resources on demand via a computer network. The resources can be embodied as various infrastructure services (e.g., compute, storage, etc.) as well as applications, databases, file services, email, etc. In the traditional model of computing, both data and software are typically fully contained on the user's computer; in cloud computing, the user's computer may contain little software or data (perhaps an operating system and/or web browser) and may serve as little more than a display terminal for processes occurring on a network of external computers. A cloud computing service (or an aggregation of multiple cloud resources) may be generally referred to as the “Cloud.” Cloud storage may include a model of networked computer data storage where data is stored on multiple virtual servers, rather than being hosted on one or more dedicated servers.

The invention is described in part below with reference to flowchart illustrations and/or block diagrams of methods, systems, computer program products and data and/or system architecture structures according to embodiments of the invention. It will be understood that each block of the illustrations, and/or combinations of blocks, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the block or blocks.

These computer program instructions may also be stored in a computer readable memory or storage that can direct a computer or other programmable data processing apparatus to function in a particular manner, such that the instructions stored in the computer readable memory or storage produce an article of manufacture including instruction means which implement the function/act specified in the block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the block or blocks.

The flowcharts and block diagrams of certain of the figures herein illustrate exemplary architecture, functionality, and operation of possible implementations of embodiments of the present invention. In this regard, each block in the flow charts or block diagrams represents a module, segment, or portion of code, which comprises one or more executable instructions for implementing the specified logical function(s). It should also be noted that in some alternative implementations, the functions noted in the blocks may occur out of the order noted in the figures. For example, two blocks shown in succession may in fact be executed substantially concurrently or the blocks may sometimes be executed in the reverse order or two or more blocks may be combined, depending upon the functionality involved.

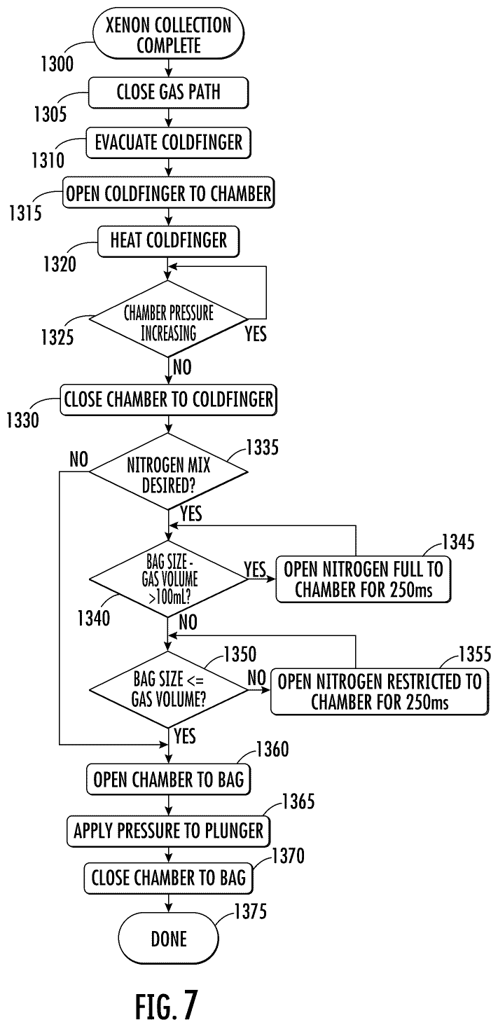

FIG. 7 is a flow chart of example actions that can be used to dispense a gas such as hyperpolarized ¹²⁹Xe. The process identifies when a xenon collection is complete (block 1300). The gas path (to the cryo-collector from the optical cell) is closed (block 1305). The gas path from the cryo-collector to the gas expansion chamber is already closed during the collection period.

The cold finger of the cryo-collector is evacuated (block 1310). The coldfinger is open to the gas expansion chamber (block 1315). The coldfinger is heated (block 1320). Pressure in the gas expansion chamber is monitored (using a pressure sensor/gauge) to detect if the chamber pressure is increasing and when it no longer is increasing, the gas expansion chamber is closed off to the coldfinger (block 1330). For a respective dispensing action, is nitrogen desired to be added (block 1335) to the collected gas in the gas expansion chamber to form a gas mixture to dispense to the dose container.

If no, the expansion gas chamber is opened to the dose container/bag (block 1360). Pressure is applied to the back side of the plunger (block 1365). The gas expansion chamber to the dose container/bag is closed once the volume of gas mixture or gas is dispensed (block 1370). The dispensing action is complete (block 1375).

If yes, determine if the dose container size/volume is greater than the desired dispense amount of gas/gas mixture by about 100 mL or more (block 1340), if yes, open the nitrogen “full flow”/unrestricted path to the gas expansion chamber for a defined time, optionally about 250 ms (block 1345). Then determine if the dose container volume is less than 100 mL of the gas volume (in the chamber after the first amount of nitrogen is added) (block 1350). If no, open the nitrogen restricted path to the chamber for a defined time such as about 250 ms (block 1355).

If yes, the expansion gas chamber is opened to the dose container/bag (block 1360). Pressure is applied to the back side of the plunger (block 1365). The gas expansion chamber to the dose container/bag is closed once the volume of gas mixture or gas is dispensed (block 1370). The dispensing action is complete (block 1375).

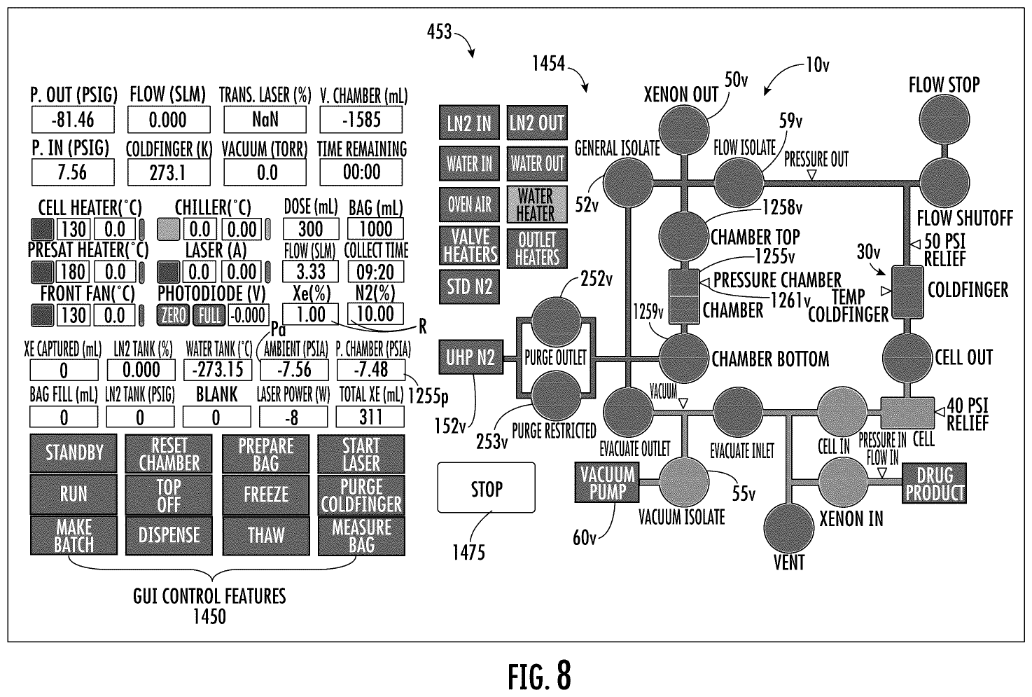

FIGS. 8-10 are displays 453 with example graphic user interface (GUI) providing a display panel with defined GUI features 1454 with control inputs and status indicators for various actions associated with the gas control dispensing system 1250 that is particularly suitable for dispensing medical grade hyperpolarized gas or gas mixtures.

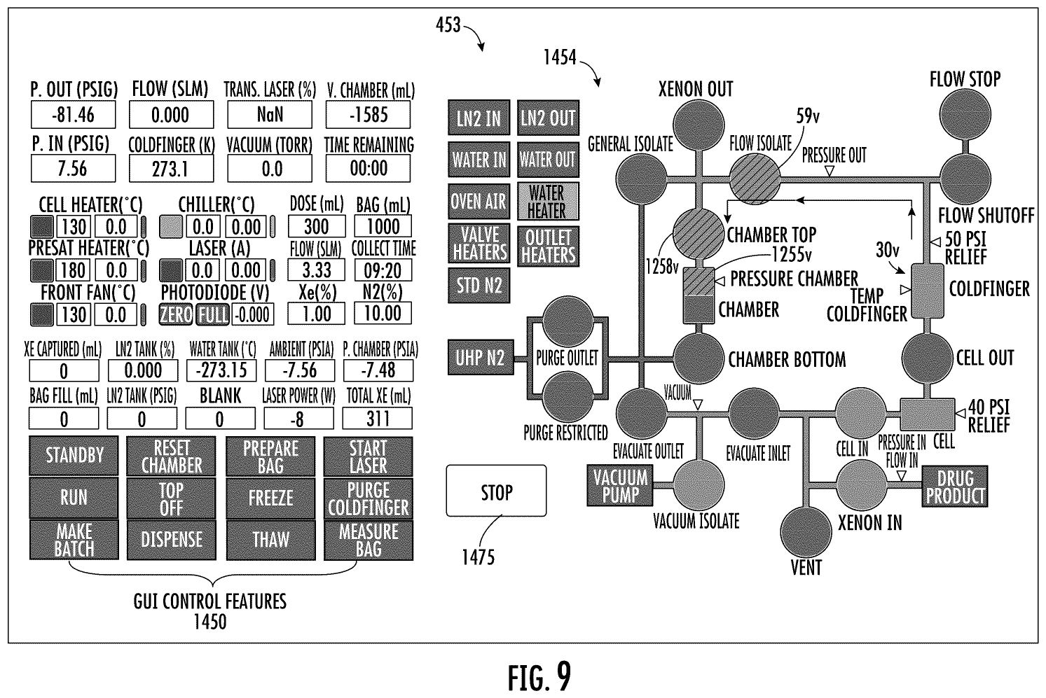

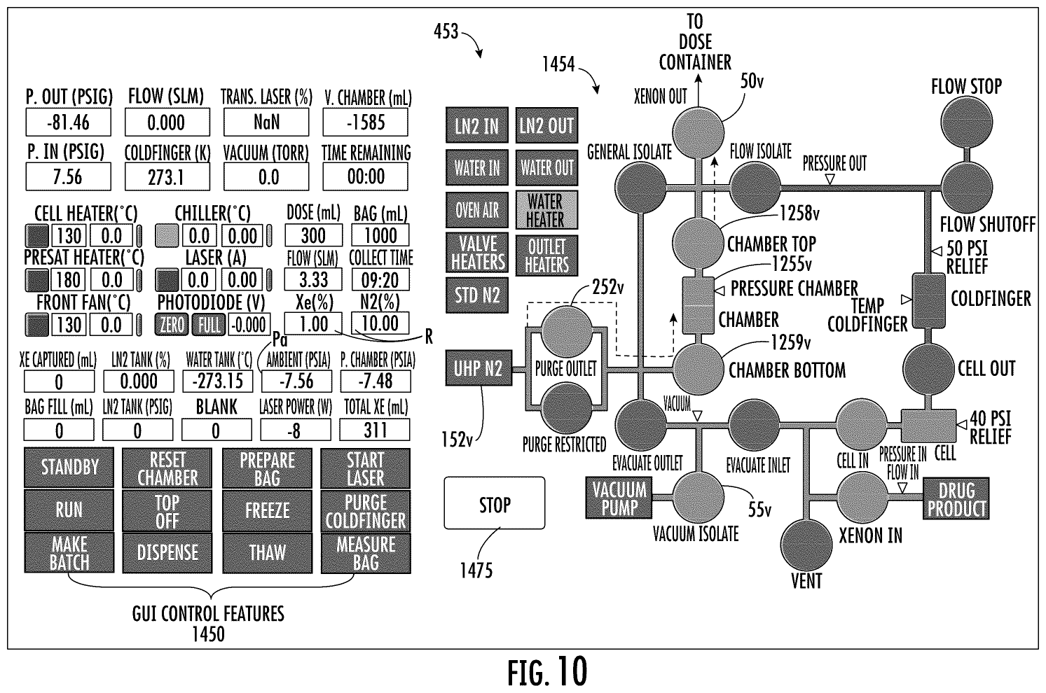

The GUI features 1454 can provide electronic virtual representations of the manifold 10m, e.g., virtual manifold 10v, and various virtual valves and components that correspond to the gas dispensing control system 1250 discussed above, e.g, virtual gas expansion chamber 1255v, virtual vacuum pump 60v, virtual valves 1258v, 1259v, 252v, 253v, 55v, 50v, for example, corresponding to the same numbers for components discussed above (without the virtual “v” designation added to the callout numbers in FIG. 8) and that provide operational status and/or controls for features of the hyperpolarizer system 10. FIG. 8 shows an operational status prior to directing gas into the gas dispensing control system 1250. FIG. 9 shows an operational status with hyperpolarized ¹²⁹Xe from the virtual cryo-collector 30v flowing into the virtual gas expansion chamber 1255v. FIG. 10 shows an operational status with nitrogen from the virtual nitrogen gas supply 152v flowing into the gas expansion chamber to force the piston toward the virtual outlet valve 50v to dispense the (measured) gas mixture from the virtual gas expansion chamber vacuum 1255v to a dose container.

As shown, the GUI control features 1450 can include standby, run, make batch, reset the gas expansion chamber, top off, dispense, prepare bag, freeze, thaw, start laser, purge coldfinger, measure bag and the like can be provided as a set at a lower left side of the display 453 although other arrangements can be used. A stop control 1475 can be visually prominently provided. The dispensing ratio R of xenon and nitrogen can be adjusted/selected and shown as well as measured ambient pressure Pa and gas expansion chamber pressure 1255p.

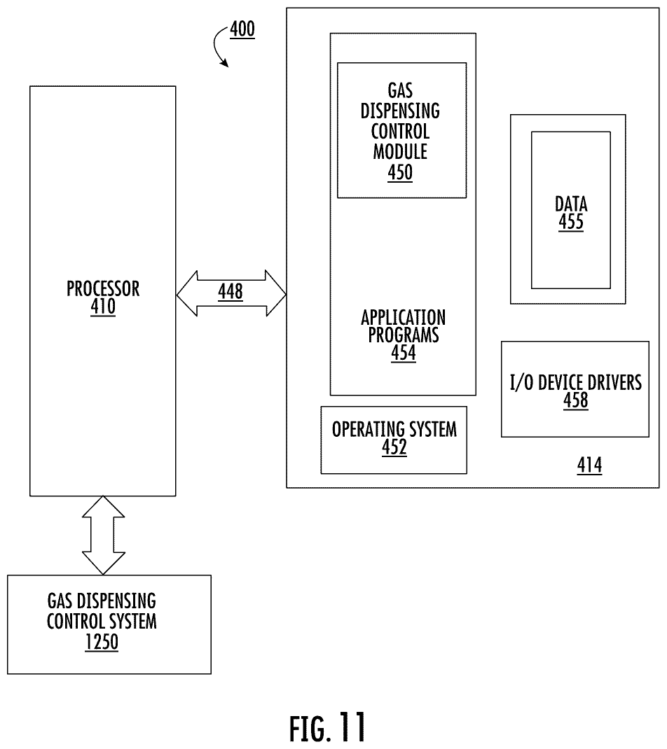

FIG. 11 is a schematic illustration of a circuit or data processing system 400. The circuits and/or data processing systems 400 may be incorporated in a digital signal processor in any suitable device or devices. As shown in FIG. 11, the processor 410 communicates with and/or is integral with the polarizer 10 and with memory 414 via an address/data bus 448. The processor 410 can be any commercially available or custom microprocessor. The memory 414 is representative of the overall hierarchy of memory devices containing the software and data used to implement the functionality of the data processing system. The memory 414 can include, but is not limited to, the following types of devices: cache, ROM, PROM, EPROM, EEPROM, flash memory, SRAM, and DRAM.

FIG. 11 illustrates that the memory 414 may include several categories of software and data used in the data processing system: the operating system 452; the application programs 454; the input/output (I/O) device drivers 458; and data 455. The data 455 can include chamber volume measurement, pressure measurement, ratio adjustment measurements of nitrogen to ¹²⁹Xe gas, a sequence control chart for synchronizing timing of manifold valves for ON/OFF position for the various actions of the dispensing process, GUI feature options and the like.

As will be appreciated by those of skill in the art, the operating systems 452 may be any operating system suitable for use with a data processing system, such as OS/2, AIX, or zOS from International Business Machines Corporation, Armonk, NY, Windows CE, Windows NT, Windows95, Windows98, Windows2000, WindowsXP, Windows Visa, Windows7, Windows 8, Windows 8.1, Windows CE or other Windows versions from Microsoft Corporation, Redmond, WA, Palm OS, Symbian OS, Cisco IOS, VxWorks, Unix or Linux, Mac OS from Apple Computer, LabView, or proprietary operating systems.

The I/O device drivers 458 typically include software routines accessed through the operating system 449 by the application programs 454 to communicate with devices such as I/O data port(s), data storage 455 and certain memory 414 components. The application programs 454 are illustrative of the programs that implement the various features of the data processing system and can include at least one application, which supports operations according to embodiments of the present invention. Finally, the data 455 represents the static and dynamic data used by the application programs 454, the operating system 452, the I/O device drivers 458, and other software programs that may reside in the memory 414.

While the present invention is illustrated, for example, with reference to the Gas Dispensing Control Circuit and/or Module (“Module”) 450 being an application program in FIG. 11, as will be appreciated by those of skill in the art, other configurations may also be utilized while still benefiting from the teachings of the present invention. For example, the Module may also be incorporated into the operating system 452, the I/O device drivers 458 or other such logical division of the data processing system. Thus, the present invention should not be construed as limited to the configuration of FIG. 11 which is intended to encompass any configuration capable of carrying out the operations described herein. Further, Module 450 can communicate with or be incorporated totally or partially in other components, such as a controller for the cryo-collection system 30 or be incorporated into a single controller and/or processor for the hyperpolarizer 10.

The I/O data port can be used to transfer information between the data processing system and another computer system or a network (e.g., the Internet) or to other devices controlled by the processor. These components may be conventional components such as those used in many conventional data processing systems, which may be configured in accordance with the present invention to operate as described herein.

By using the large expansion chamber (˜3100 mL), the gas dispensing system 1250 can be configured so that there is only about a 2.5% loss to dead space when used with some hyperpolarizer geometry including a conventional cryo-collector condenser. For the existing system this loss varies based on the volume of gas polarized. For a net 250 mL dose, 330 mL is typically prepared, and 80 mL, or 24.2%, is lost. Even for 750 mL dose, 830 mL is typically required to be prepared. Again, 80 mL, or 9.6%, is lost to the dead volume.

By using pressure, the systems can be configured to have an uncertainty in the measurement of volume of 0.27%. For a 250 mL dose that is 0.7 mL. For 750 mL that is 2.0 mL. For 1000 mL it is 2.7 mL. For a conventional syringe used for this purpose, the gradations are in 20 mL increments. Assuming the plunger is positioned so the pressure inside the syringe and outside the syringe are equal, 10 mL can be assumed to be the uncertainty in all the measurements. So, for 250 mL that is 4%, and for 1000 mL, this is 1%. In actual applications, it has an even larger uncertainty due to pressure imbalance between the interior and exterior of the syringe.

Prior known gas dispensing systems using a syringe system do not measure standard mL which is what is important for determining quantity of polarized nuclei (unless the local atmospheric pressure is 760 Torr).

Multiple doses from the same batch with the same xenon/nitrogen ratios can be dispensed with accurate measurement of the quantities dispensed for each.

Multiple doses with differing xenon/nitrogen ratios can be dispensed with accurate measurement of the quantities dispensed for each.

The gas control system 1250 can be automated with only valves, pressure transducers, and temperature sensors to provide local ambient conditions.

The present invention facilitates the accurate measurement of hyperpolarized noble gasses for dispensing into dose containers 155.

Embodiments of the present invention allow for the automated blending of gas mixtures in particular those containing a noble gas and nitrogen.

Embodiments of the present invention allow for accurate measurement of a final blended dose of hyperpolarized noble gas and another gas for a gas mixture to be dispensed to a dose container 155.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clause are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

That which is claimed is:

1. A gas dispensing control system, comprising:
a gas expansion chamber comprising a first end portion, a second end portion opposing and spaced apart from the first end portion, and a plunger in the expansion chamber configured to travel between the first end portion and the second end portion;
a first valve coupled to the first end portion of the gas expansion chamber and in fluid communication with a nitrogen gas supply;
a second valve coupled to the second end portion of the gas expansion chamber and in fluid communication with the nitrogen gas supply; and
a controller in communication with the first valve and the second valve to direct the first valve to be in an open state and the second valve to be in a closed state or direct the second valve to be in an open state and the first valve to be in a closed state so that nitrogen gas from the nitrogen gas supply either:
enters the first end portion of the gas expansion chamber, or
enters the second end portion of the gas expansion chamber.

2. The gas dispensing control system of claim 1, wherein the gas expansion chamber has a volume in a range of about 3000 mL to about 4000 mL.

3. The gas dispensing control system of claim 1, further comprising a vacuum pump coupled to an evacuation outlet valve that is in communication with the controller and controllably operated so that the vacuum pump is in fluid communication with the first end portion of the gas expansion chamber or the second end portion of the vacuum chamber whereby spaces inside the gas expansion chamber on opposing sides of the plunger are evacuated at different times.

4. The gas dispensing control system of claim 1, further comprising a Helmholtz coil extending about the gas expansion chamber.

5. The gas dispensing control system of claim 1, wherein the gas mixture comprises hyperpolarized ¹²⁹Xe and the nitrogen, and wherein the controller is configured to provide a defined ratio of nitrogen to the hyperpolarized ¹²⁹Xe in the gas expansion chamber.

6. The gas dispensing control system of claim 1, further comprising a pressure sensor adjacent the expansion chamber and in communication with the controller, wherein the controller is configured to calculate a standard milliliter quantity of gas in the expansion chamber based on one or more measurements of local atmospheric pressure based on data from the pressure sensor.

7. The gas dispensing control system of claim 1, further comprising:
a fluid manifold coupled to the gas expansion chamber, the nitrogen gas supply, a gas collection system and a gas dispensing outlet;
a vacuum pump coupled to the fluid manifold;
an evacuation outlet valve coupled to the fluid manifold adjacent the vacuum pump;
a gas dispensing outlet valve upstream of the gas dispensing outlet;
a first isolation valve positioned at a first position of the fluid manifold upstream of the gas dispensing outlet valve;
a second isolation valve spaced apart from the first isolation valve and positioned at a second position of the fluid manifold, also upstream of the gas dispensing outlet valve; and
a nitrogen outlet flow valve coupled to the fluid manifold between the nitrogen gas supply and the gas expansion chamber,
wherein the evacuation outlet valve, the gas dispensing outlet valve, the first isolation valve and the second isolation valve are all in communication with the controller, and wherein the controller is configured to control sets of respective valves between on and off positions comprising:
(i) close the nitrogen outlet flow valve, the first isolation valve, the second isolation valve and the first valve coupled to the gas expansion chamber and open the evacuation outlet valve and the second valve coupled to the gas expansion chamber and pull a first vacuum (optionally about 300 Torr) on a back side of the gas expansion chamber between the plunger and the second end portion of the gas expansion chamber to at least partially retract the plunger;
(ii) close the evacuation outlet valve and the second valve coupled to the gas expansion chamber and open the nitrogen outlet flow valve, the first isolation valve and the first valve coupled to the gas expansion chamber to flow nitrogen into the gas expansion chamber and pressurize a front side of the gas expansion chamber (optionally to about 35 PSIA) between the plunger and the first end portion of the gas expansion chamber;
(iii) close the nitrogen outlet flow valve and the first valve coupled to the gas expansion chamber and open the evacuation outlet valve and the second valve coupled to the gas expansion chamber to pull a second vacuum on the back side of the plunger, with the second vacuum being at a greater vacuum level (optionally about 1 Torr) to retract the plunger to a fully retracted position at the second end portion of the gas expansion chamber; and
(iv) with the second valve coupled to the gas expansion chamber open, or direct the second valve to open, and open the first valve coupled to the gas expansion chamber to evacuate both the back side and the front side of the gas evacuation chamber thereby providing a reset status for the gas expansion chamber to thereby be in a state ready to receive gas from the gas collection system.

8. The gas dispensing control system of claim 7, wherein the gas collection system is a cryo-collection gas collection system that freezes, then thaws, collected hyperpolarized ¹²⁹Xe, wherein when a cryo-collection accumulation is complete, the controller is configured to:
(v) close the gas dispensing outlet valve, the first isolation valve, the evacuation outlet valve, and the second valve coupled to the gas expansion chamber and open the second flow isolation valve with the first valve coupled to the gas expansion chamber open so that thawed ¹²⁹Xe gas flows into the gas expansion chamber; and
(vi) open the first isolation valve and the nitrogen outlet flow valve to direct a controlled amount of nitrogen into the gas expansion chamber with the ¹²⁹Xe to form a gas mixture.

9. The gas dispensing control system of claim 8, wherein the gas dispensing control system is configured to dispense the gas mixture into a dose bag coupled to the gas dispensing outlet by closing the first isolation valve, opening the gas dispensing outlet valve, opening the nitrogen outlet flow valve and the second valve coupled to the gas expansion chamber to pressurize the back side of the plunger and move the plunger toward the first end portion of the gas expansion chamber.

10. The gas dispensing control system of claim 7, wherein the nitrogen outlet flow valve is provided as a first nitrogen outlet flow valve and a second nitrogen outlet flow valve, wherein the fluid manifold comprises a nitrogen flow path comprising a first nitrogen branch between the nitrogen gas supply and the first nitrogen outlet flow valve and a second nitrogen branch between the second nitrogen outlet flow valve and the nitrogen gas supply, wherein the first nitrogen branch and the second nitrogen branch merge into a nitrogen feed channel that extends between the second end portion of the gas expansion chamber and the first end portion of the gas expansion chamber.

11. The gas dispensing control system of claim 1, wherein the plunger is moved in the gas expansion chamber between first and second opposing directions only by automatically applied pressure directed by the controller to thereby apply pressure to a first side or a second side of the plunger.

12. The gas dispensing control system of claim 1, further comprising:
a nitrogen flow control valve in fluid communication with the nitrogen gas supply;
a vacuum pump in fluid communication with the gas expansion chamber;
an evacuation outlet valve between the gas expansion chamber and the vacuum pump;
a first flow isolation valve;
a second flow isolation valve; and
a gas dispensing outlet valve,
wherein the controller is also in communication with the gas dispensing outlet valve, the evacuation outlet valve, the first flow isolation valve and the second flow isolation valve.

13. The gas dispensing control system of claim 1, further comprising a fluid manifold coupled to the gas expansion chamber and the nitrogen gas supply, wherein the fluid manifold comprises a nitrogen flow path comprising a first branch with a first branch valve and a second branch with a second branch valve, each downstream of the nitrogen supply and upstream of the gas expansion chamber.

14. The gas dispensing control system of claim 13, wherein the second branch comprises a restricted segment upstream of the second branch valve.

15. The gas dispensing control system of claim 1, further comprising a gas outlet path with a gas outlet valve positioned between the first valve and a dispensing outlet coupled to a gas collection container.

16. The gas dispensing control system of claim 1, wherein the gas expansion chamber is in fluid communication with a cryo-collection system, and wherein the first valve is configured to open to flowably receive a quantity of hyperpolarized ¹²⁹Xe gas.

17. The gas dispensing control system of claim 1, further comprising a display providing a user interface for controlling operational components of the gas dispensing control system and visually providing operational status data of the gas dispensing control system.

18. A flow-through spin exchange optical pumping (SEOP) hyperpolarized gas production system for producing hyperpolarized gas comprising:
a pressurized gas mixture;
a flow-through optical pumping cell in fluid communication with the pressurized gas mixture;
a cryo-collection system downstream of and in fluid communication with the flow-through optical pumping cell; and
the gas dispensing control system of claim 1 in fluid communication with the SEOP hyperpolarized gas production system.

19. The flow-through SEOP gas production system of claim 18, further comprising a flexible patient dose delivery bag downstream of the gas expansion chamber and coupled to a gas dispensing outlet.

20. A method of dispensing hyperpolarized ¹²⁹Xe, comprising:
providing a gas control dispensing system comprising a gas expansion chamber with a plunger in communication with a vacuum pump and a nitrogen supply;
directing nitrogen from the nitrogen supply into a first end portion of the gas expansion chamber in front of the plunger;
evacuating a back side space of the gas expansion chamber in back of the plunger to further or fully retract the plunger; then
evacuating a front side of the gas expansion chamber to place the gas expansion chamber in a ready state for receiving hyperpolarized ¹²⁹Xe gas; then
directing hyperpolarized ¹²⁹Xe gas from a gas collection system to flow into the first end portion of the gas expansion chamber; and then
directing nitrogen from the nitrogen gas supply to flow into the second end portion of the gas expansion chamber to move the plunger a defined amount to force a defined volume of the ¹²⁹Xe gas or a gas mixture with the ¹²⁹Xe and nitrogen out of the first end portion of the gas expansion chamber and into a container.

21. The method of claim 20, further comprising:
electronically determining local atmospheric pressure;
calculating a volume of ¹²⁹Xe gas or a volume of a gas mixture with the ¹²⁹Xe in the expansion gas chamber based on the local atmospheric pressure; and
automatically controlling the plunger to move to dispense ¹²⁹Xe based on, at least in part, the calculated volume.

22. The method of claim 20, further comprising, before directing nitrogen from the nitrogen gas supply to flow into the second end portion of the gas expansion chamber to move the plunger, automatically directing nitrogen from the nitrogen gas supply into the first end portion of the gas expansion chamber to form a gas mixture with a defined ratio of nitrogen to the hyperpolarized ¹²⁹Xe gas in the gas mixture.

23. The method of claim 22, further comprising allowing a user to controllably alter the defined ratio of nitrogen to ¹²⁹Xe gas to thereby provide different dispensed ratios of the gas mixture into different containers.
